(19) United States
(12) Patent Application Publication
(10) Pub. No.: US 2025/0105061 A1
(43) Pub. Date: Mar. 27, 2025

(54) SELF-ALIGNED CONTACT FOR FIELD EFFECT TRANSISTORS

(71) Applicant: INTERNATIONAL BUSINESS MACHINES CORPORATION, ARMONK, NY (US)

(72) Inventors: James P. Mazza, Saratoga Springs, NY (US); Ruilong Xie, Niskayuna, NY (US); Koichi Motoyama, Clifton Park, NY (US); Nicholas Anthony Lanzillo, Wynantskill, NY (US)

(21) Appl. No.: 18/471,408

(22) Filed: Sep. 21, 2023

(51) Int. Cl. H01L 21/768; H01L 21/822; H01L 21/8238; H01L 23/535; H01L 27/092; H01L 29/06; H01L 29/417; H01L 29/423; H01L 29/66; H01L 29/775

(52) U.S. Cl. CPC H01L 21/76897; H01L 23/535; H10D 30/014; H10D 30/43; H10D 30/6729; H10D 30/6735; H10D 62/121; H10D 64/017; H10D 84/0167; H10D 84/017; H10D 84/0186; H10D 84/038; H10D 84/856; H10D 88/01

(57) ABSTRACT

A semiconductor structure extends laterally with an interconnect on one side and another interconnect on an opposing side separated by a thickness of the semiconductor structure that extends longitudinally. The semiconductor structure includes an insulating member extending laterally, a source/drain (S/D) positioned in the insulating member between the interconnects, another S/D positioned in the insulating member between the first S/D and one of the interconnects, wherein the S/Ds laps each other laterally and are offset from each other longitudinally, and a via electrically connected to the first S/D and to the aforementioned one of the interconnects.

### BACKGROUND

The present invention relates to semiconductor devices, and more specifically, to vias between layers in an integrated circuit.

Field-effect transistors (“FETs”) use an electric field effect to control current flow within a semiconductor. Specifically, FETs may use the electric charge of their gates to affect and control the current flow through a channel. One type of FET is a stacked FET, and stacked FETs have at least two FETs that are vertically aligned with one being above the other. The FETs can then be connected to a frontside or a backside interconnect. For example, the bottom FET can be nearest to the backside interconnect (compared to the top FET), and the top FET can be nearest to the frontside interconnect (compared to the bottom FET), so their respective connections can be relatively easy to make. However, connecting a FET to the opposite side (e.g., connecting the bottom FET to the frontside) can be difficult, for example, due to the distance that needs to be traversed.

### SUMMARY

According to one embodiment of the present disclosure, a semiconductor structure extends laterally with an interconnect on one side and another interconnect on an opposing side separated by a thickness of the semiconductor structure that extends longitudinally. The semiconductor structure includes an insulating member extending laterally, a source/drain (S/D) positioned in the insulator between the interconnects, another S/D positioned in the insulator between the first S/D and one of the interconnects, wherein the S/Ds lap each other laterally and are offset from each other longitudinally, and a via electrically connected to the first S/D and to the aforementioned one of the interconnects.

According to another embodiment of the present disclosure, a method of forming a semiconductor structure includes forming a first source/drain (S/D) in a first device materials, bonding a second device materials to the first device materials using a bonding dielectric, forming a dummy gate and a spacer in the second device materials, forming a second S/D contact placeholder in the bonding dielectric, and forming a second S/D in the second device materials. The method also includes forming a deep via trench in the first device materials, in the second device materials, and in the contact placeholder, forming a via in the deep via trench that is electrically connected to the second S/D, forming a second-side interconnect on the second device materials, forming a local interconnect in the second device materials that intersects an axis of the via but is electrically insulated from the via, and forming a first-side interconnect on the first device materials.

According to another embodiment of the present disclosure, a semiconductor structure extends laterally with a first interconnect on one side and a second interconnect on an opposing side separated from the first interconnect by a thickness of the semiconductor structure that extends longitudinally. The semiconductor structure includes an insulating member extending laterally, a first source/drain (S/D) positioned in the insulator between the first interconnect and the second interconnect, a second S/D positioned in the insulator between the first interconnect and the second interconnect, wherein the second S/D laps the first S/D longitudinally and is offset from the first S/D laterally, and a local interconnect that is electrically connected to the second S/D and to the first interconnect and is electrically insulated from the first S/D. The local interconnect laps the first S/D laterally and is offset from the first S/D longitudinally.

### BRIEF DESCRIPTION OF THE DRAWINGS

FIGS. 1A and 1B are a series of cross-section views of a semiconductor structure, in accordance with embodiments of the present disclosure.

FIG. 2 is a flowchart of a method of manufacturing the semiconductor structure of FIG. 1A, in accordance with an embodiment of the present disclosure.

FIGS. 3A-3R are a series of cross-section views of stages in a manufacture of the semiconductor structure according to the method of FIG. 2, in accordance with an embodiment of the present disclosure.

### DETAILED DESCRIPTION

The following are non-exclusive descriptions of some example embodiments of the present disclosure.

An example semiconductor structure extends laterally with a first interconnect on one side and a second interconnect on an opposing side separated from the first interconnect by a thickness of the semiconductor structure that extends longitudinally. The semiconductor structure, according to an example embodiment of this disclosure, among other possible things, includes: an insulating member extending laterally; a first source/drain (S/D) positioned in the insulator between the first interconnect and the second interconnect; a second S/D positioned in the insulator between the first S/D and the second interconnect, wherein the second S/D laps the first S/D laterally and is offset from the first S/D longitudinally; and a first via electrically connected to the first S/D and to the second interconnect. Such an embodiment can provide the technical effect and/or advantage of allowing a front side FET to be communicatively connected to the bottom interconnect.

The semiconductor structure of the preceding paragraph can optionally include, additionally and/or alternatively, any one or more of the following features, configurations, and/or additional components.

A further embodiment of the foregoing semiconductor structure includes a third S/D positioned in the insulator between the first interconnect and the second interconnect, wherein the third S/D laps the first S/D longitudinally and is offset from the first S/D laterally; and a local interconnect that is electrically connected to the third S/D and to the first interconnect and is electrically insulated from the first S/D; wherein the local interconnect laps the first S/D laterally and is offset from the first S/D longitudinally. Such an embodiment can provide the technical effect and/or advantage of increasing the computing power of the semiconductor structure by utilizing space for a computing component that would otherwise be merely occupied by insulating material.

A further embodiment of any of the foregoing semiconductor structures includes a second via electrically connected to the second S/D and to the second interconnect. Such an embodiment can provide the technical effect and/or advantage of allowing the second S/D to be to be communicatively connected to the second interconnect.

A further embodiment of any of the foregoing semiconductor structures includes a contact connected to the first S/D on a side nearest to the second S/D. Such an embodiment can provide the technical effect and/or advantage of having the contact be self-aligned with the first S/D.

In a further embodiment of any of the foregoing semiconductor structures, the insulating member comprises a bonding dielectric layer longitudinally positioned between the first S/D and the second S/D. Such an embodiment can provide the technical effect and/or advantage of allowing the semiconductor structure to have a stacked FET configuration.

In a further embodiment of any of the foregoing semiconductor structures, the contact is positioned in the bonding layer. Such an embodiment can provide the technical effect and/or advantage of the contact being electrically isolated from the second S/D.

In a further embodiment of any of the foregoing semiconductor structures, the first via is electrically connected to the first S/D through the contact. Such an embodiment can provide the technical effect and/or advantage of allowing the via to extend to the second interconnect without passing through the first S/D.

In a further embodiment of any of the foregoing semiconductor structures, the contact is a same width as the first S/D in a first lateral direction, and the contact is a larger width than the first S/D in a second, different lateral direction. Such an embodiment can provide the technical effect and/or advantage of having the contact be self-aligned with the first S/D and allowing the via to extend to the second interconnect without passing through the first S/D.

A further embodiment of any of the foregoing semiconductor structures includes a second via electrically connected to the second S/D and to the second interconnect. Such an embodiment can provide the technical effect and/or advantage of allowing the second S/D to be communicatively connected to the second interconnect.

A further embodiment of any of the foregoing semiconductor structures includes a third S/D positioned in the insulator between the first interconnect and the second interconnect, wherein the third S/D laps the second S/D longitudinally and is offset from the second S/D laterally, wherein the third S/D is electrically connected to the first interconnect. Such an embodiment can provide the technical effect and/or advantage of increasing the computing power of the semiconductor structure by utilizing space for a computing component that would otherwise be merely occupied by insulating material.

An example method of forming a semiconductor structure, according to an example embodiment of this disclosure, among other possible things, includes: forming a first source/drain (S/D) in a first device materials; bonding a second device materials to the first device materials using a bonding dielectric; forming a dummy gate and a spacer in the second device materials; forming a second S/D contact placeholder in the bonding dielectric; forming a second S/D in the second device materials; forming a deep via trench in the first device materials, in the second device materials, and in the contact placeholder; forming a via in the deep via trench that is electrically connected to the second S/D; forming a second-side interconnect on the second device materials; forming a local interconnect in the second device materials that intersects an axis of the via but is electrically insulated from the via; and forming a first-side interconnect on the first device materials. Such an embodiment can provide the technical effect and/or advantage of allowing a front side FET with a self-aligned S/D to be communicatively connected to the bottom interconnect.

The method of the preceding paragraph can optionally include, additionally and/or alternatively, any one or more of the following features, configurations, and/or additional components.

In a further embodiment of the foregoing method, the method further includes removing a remaining portion of the contact placeholder; and the forming the local interconnect is performed such that the local interconnect intersects an axis extending between the first S/D and the second S/D. Such an embodiment can provide the technical effect and/or advantage of utilizing available space in the insulating member for routing an interconnect.

In a further embodiment of any of the foregoing methods, forming the second-side interconnect comprises removing a portion of the second device materials and forming the second-side interconnect on a remaining second device materials. Such an embodiment can provide the technical effect and/or advantage of allowing the local interconnect to be created and communicatively connected to the second-side interconnect.

A further embodiment of any of the foregoing methods includes forming a void in the second device materials prior to forming the second S/D contact placeholder such that the second S/D is self-aligned with the second S/D contact. Such an embodiment can provide the technical effect and/or advantage of ensuring an electrical connection between the second S/D and the second S/D contact.

In a further embodiment of any of the foregoing methods, forming the via comprises forming a contact in a void left by the removal of the remaining portion of the contact placeholder, wherein the contact is electrically connected to the deep via trench and to the second S/D. Such an embodiment can provide the technical effect and/or advantage of allowing the via to extend to the second interconnect without passing through the second S/D.

In a further embodiment of any of the foregoing methods, wherein the forming the local interconnect comprises electrically connecting the local interconnect to a third S/D and to the second-side interconnect but not to the second S/D. Such an embodiment can provide the technical effect and/or advantage of allowing the third S/D to be to be communicatively connected to the second-side interconnect.

In a further embodiment of any of the foregoing methods, forming the first-side interconnect comprises removing a portion of the first device materials and forming the first-side interconnect on a remaining first device materials. Such an embodiment can provide the technical effect and/or advantage of allowing the first S/D to be communicatively connected to the first-side interconnect.

An example semiconductor structure extends laterally with a first interconnect on one side and a second interconnect on an opposing side separated from the first interconnect by a thickness of the semiconductor structure that extends longitudinally. The semiconductor structure, according to an example embodiment of this disclosure, among other possible things, includes: an insulating member extending laterally; a first source/drain (S/D) positioned in the insulator between the first interconnect and the second interconnect; a second S/D positioned in the insulator between the first interconnect and the second interconnect, wherein the second S/D laps the first S/D longitudinally and is offset from the first S/D laterally; and a local interconnect that is electrically connected to the second S/D and to the first interconnect and is electrically insulated from the first S/D; wherein the local interconnect laps the first S/D laterally and is offset from the first S/D longitudinally. Such an embodiment can provide the technical effect and/or advantage of allowing local interconnects to be placed above the front side FET.

The semiconductor structure of the preceding paragraph can optionally include, additionally and/or alternatively, any one or more of the following features, configurations, and/or additional components.

A further embodiment of the foregoing semiconductor structure includes a first via electrically connected to the first S/D and to the second interconnect. Such an embodiment can provide the technical effect and/or advantage of allowing a front side FET to be communicatively connected to the second interconnect.

A further embodiment of any of the foregoing semiconductor structures includes a third S/D positioned in the insulator between the first S/D and the second interconnect, wherein the third S/D laps the first S/D laterally and is offset from the first S/D longitudinally. Such an embodiment can provide the technical effect and/or advantage of increasing the computing power of the semiconductor structure by utilizing space for a computing component that would otherwise be merely occupied by insulating material.

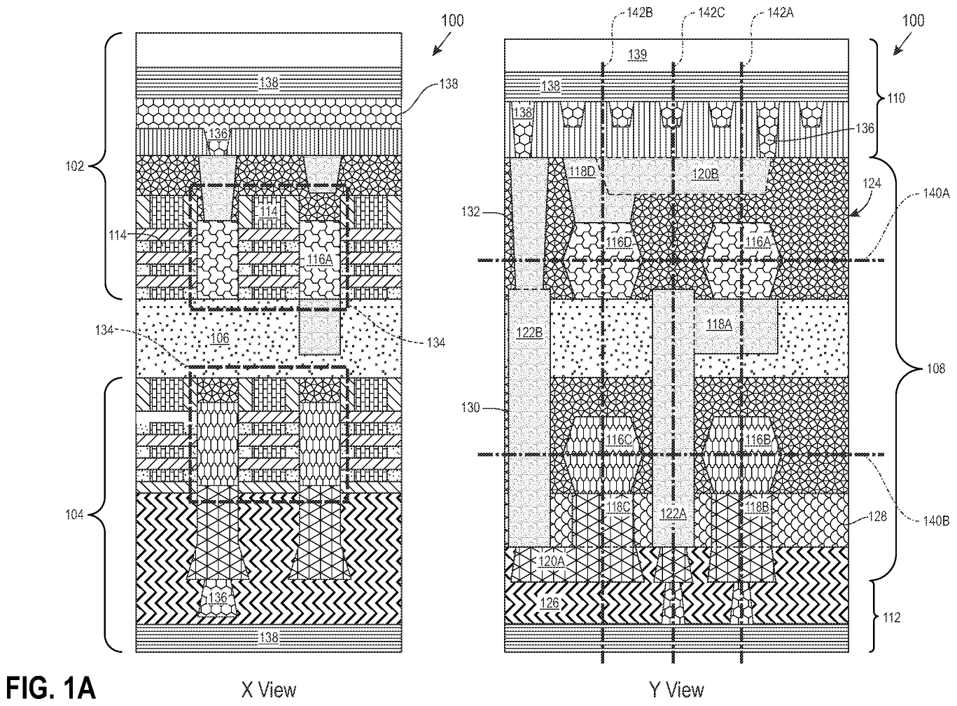

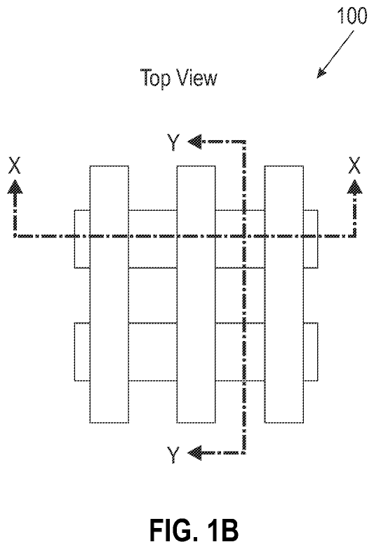

FIGS. 1A and 1B are a series of cross-section views of semiconductor structure 100. FIG. 1A includes an X View and a Y View, and FIG. 1B includes a Top View. The orientation of X View is indicated by line X-X in the Top View, and the orientation of Y View is indicated by line Y-Y in the Top View.

In the illustrated embodiment, semiconductor structure 100 comprises top channel 102 (a.k.a., the frontside of semiconductor structure 100), bottom channel 104 (a.k.a., the backside of semiconductor structure 100), and bonding layer 106. Bonding layer 106 connects top channel 102 and bottom channel 104 together and is comprised of an oxide material or a nitride material.

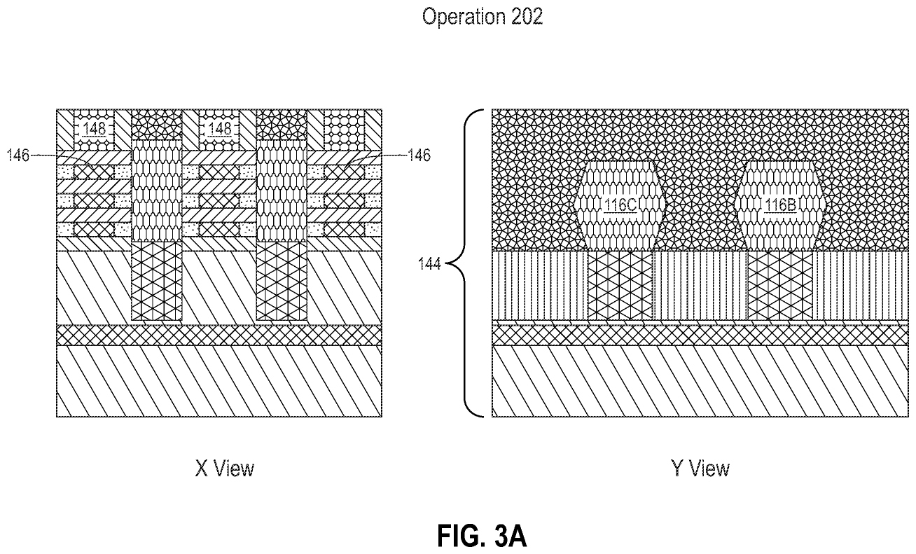

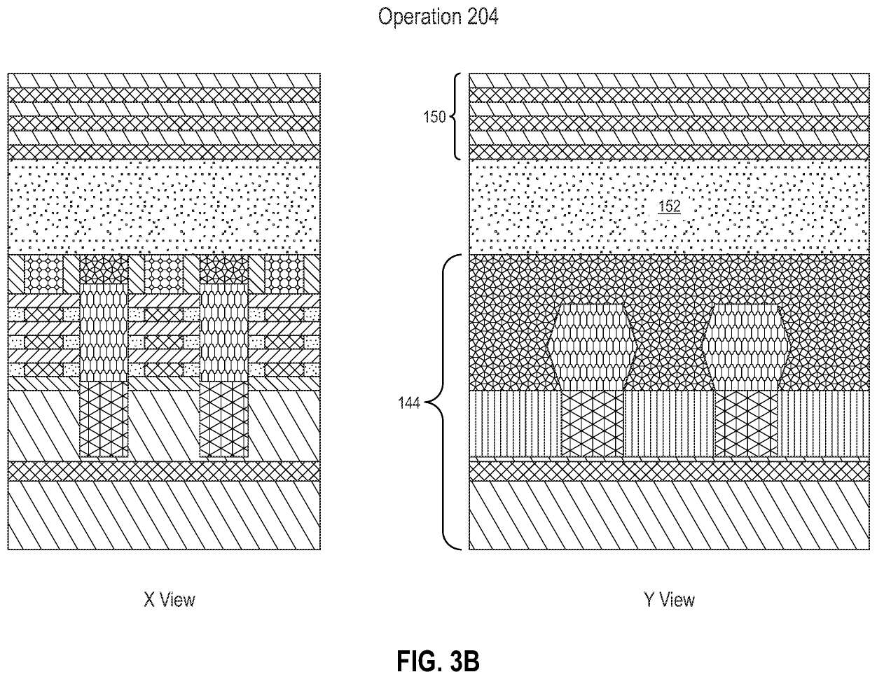

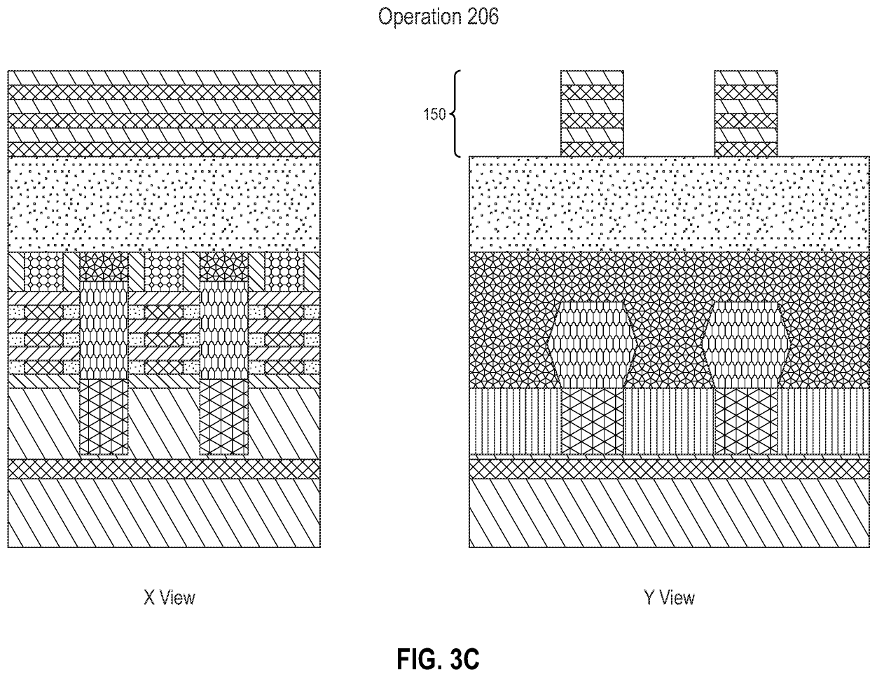

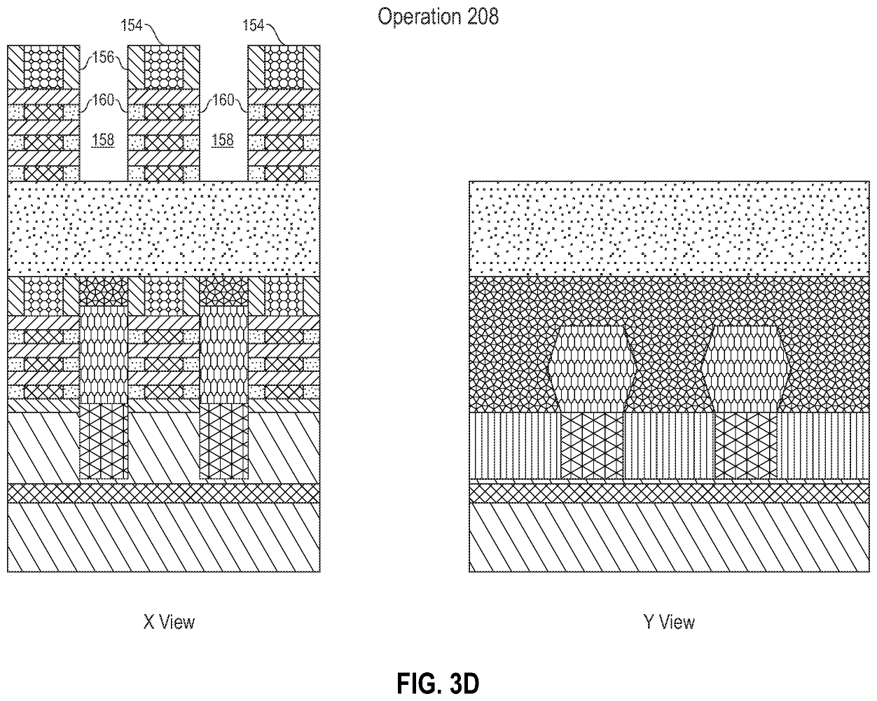

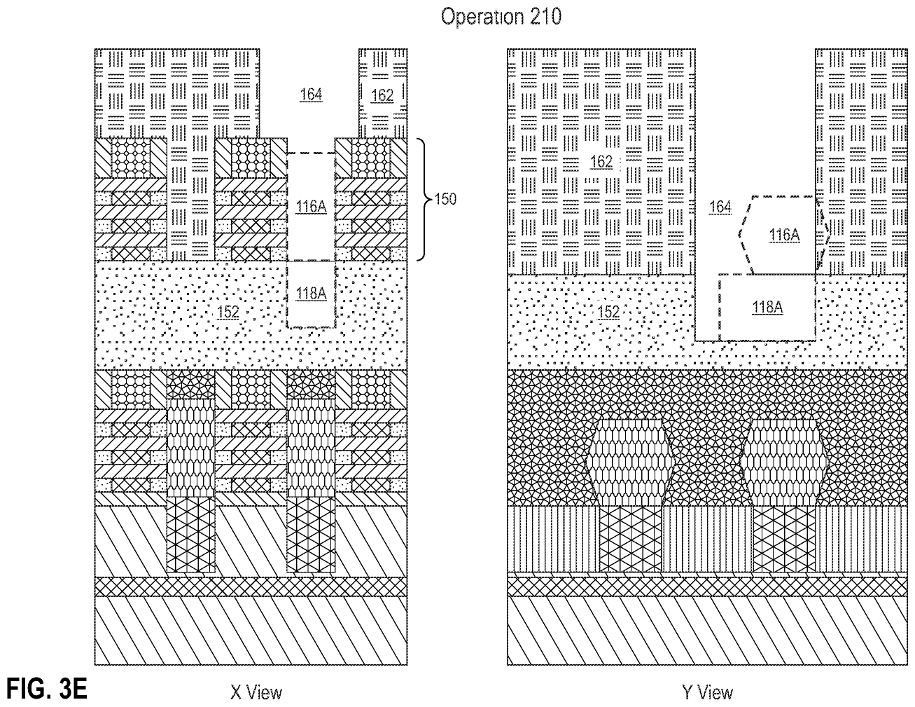

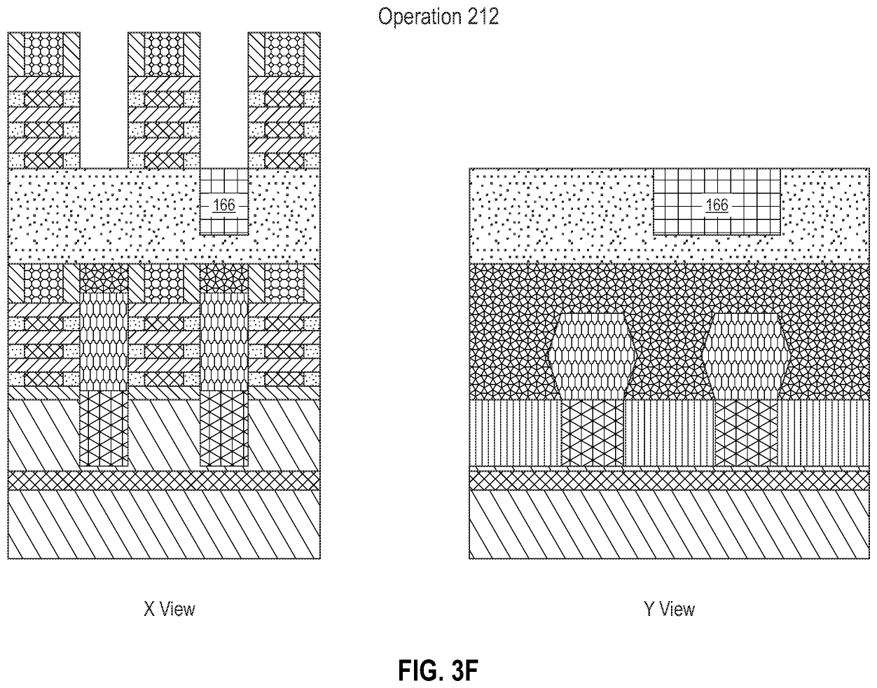

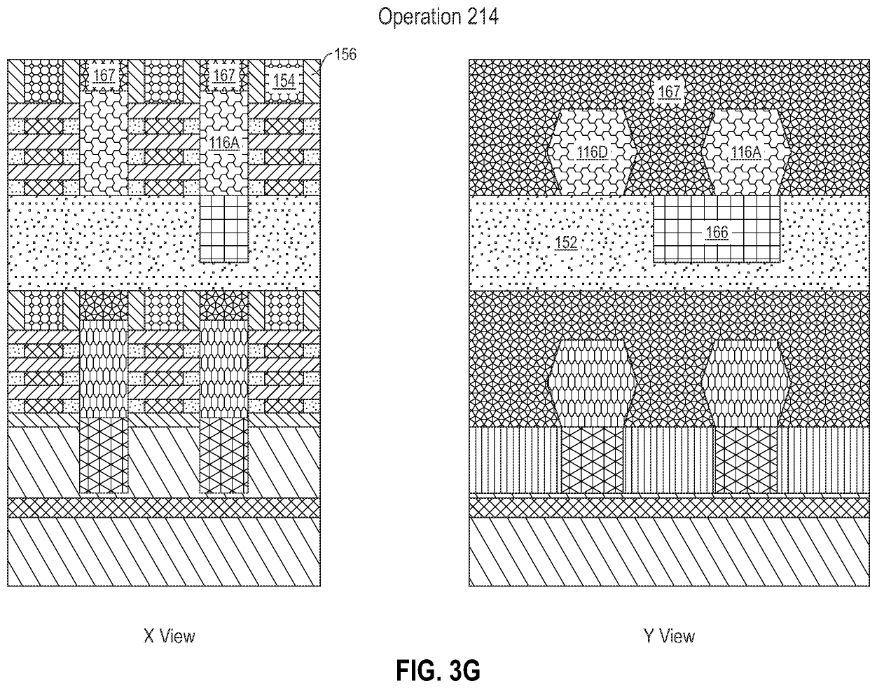

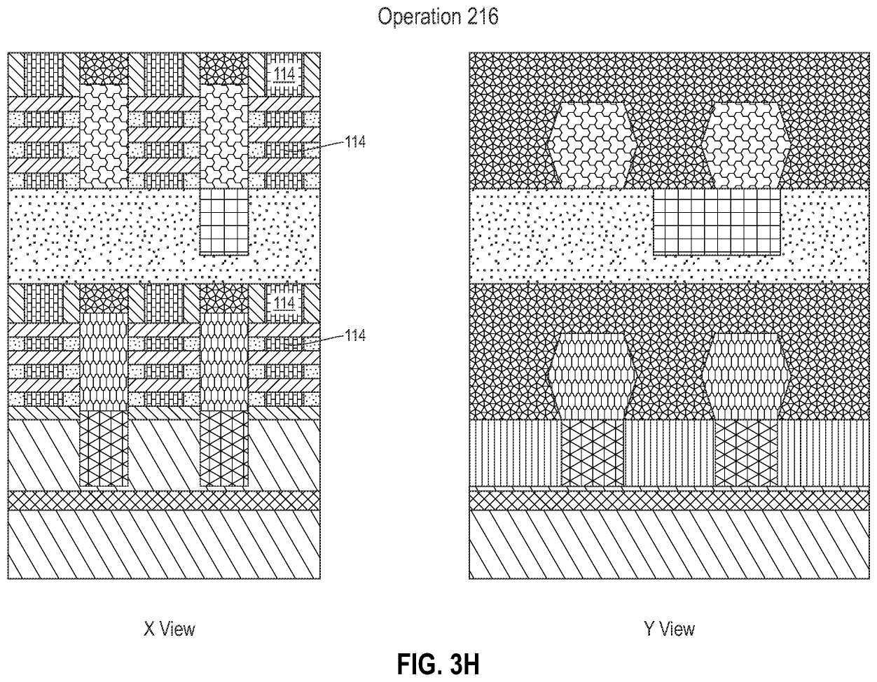

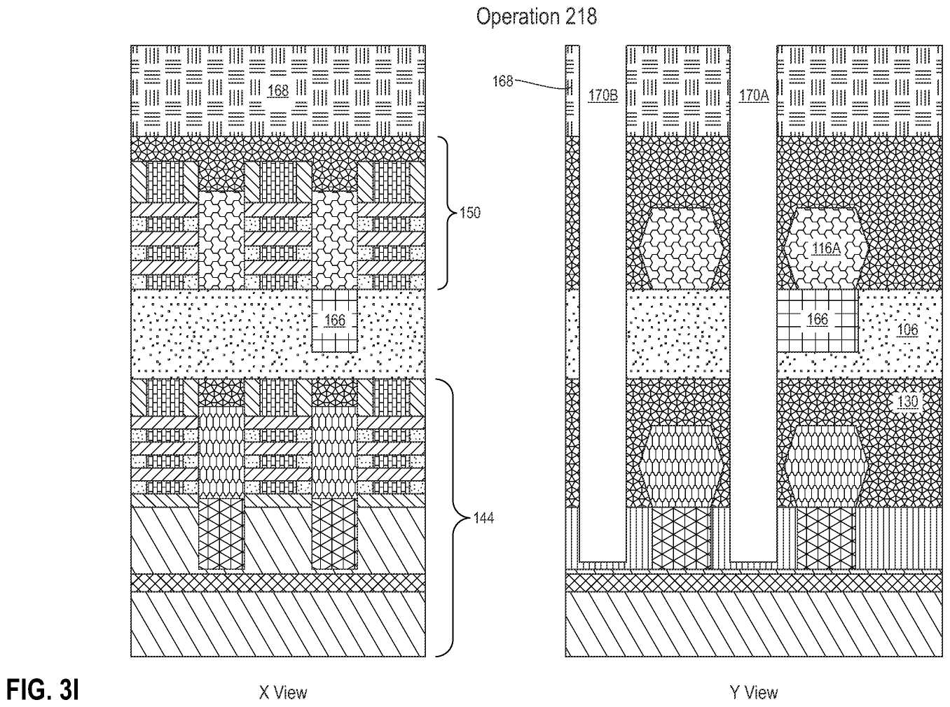

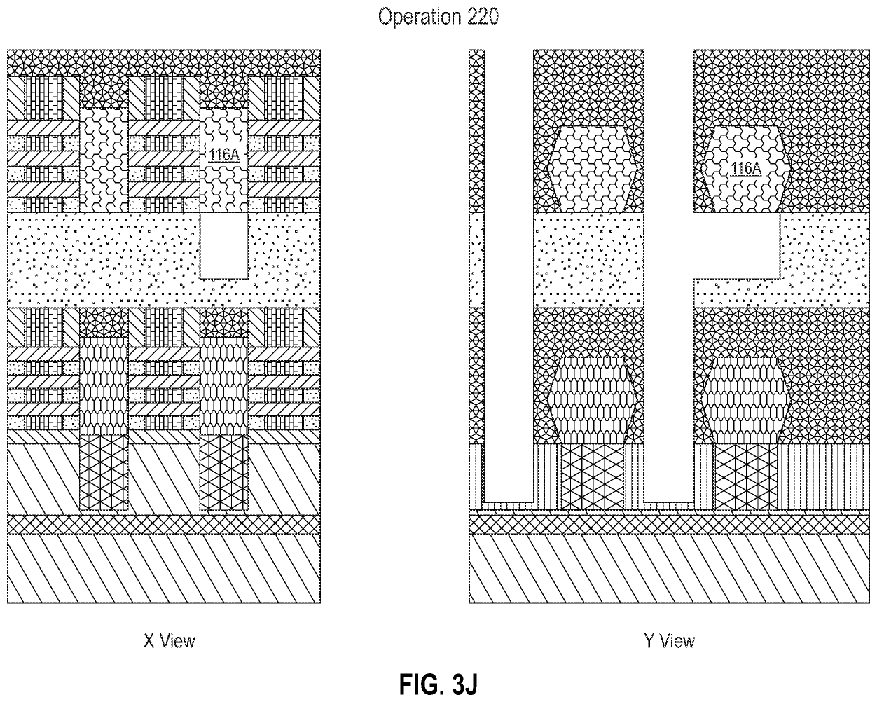

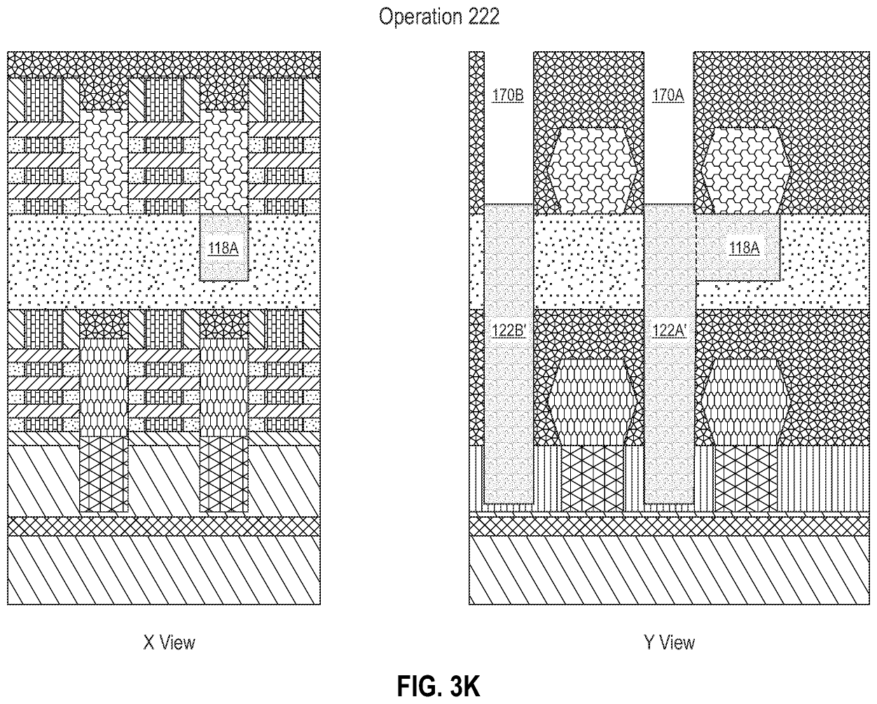

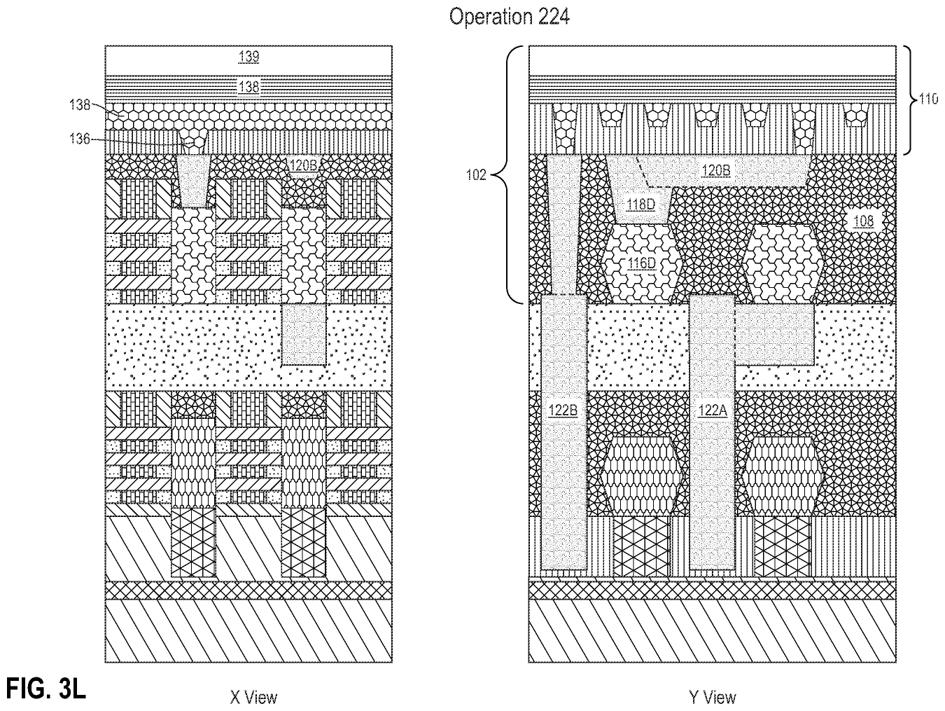

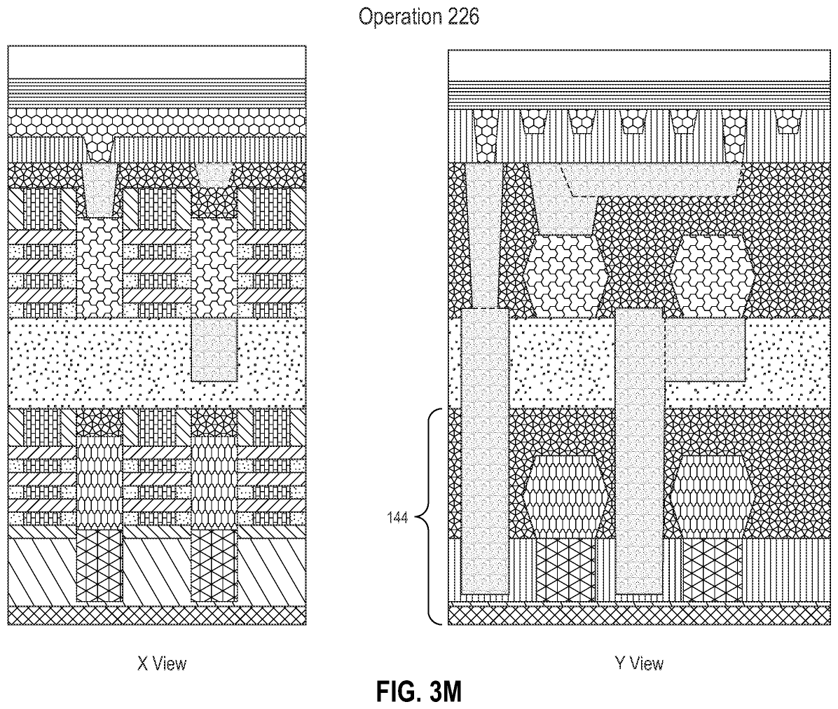

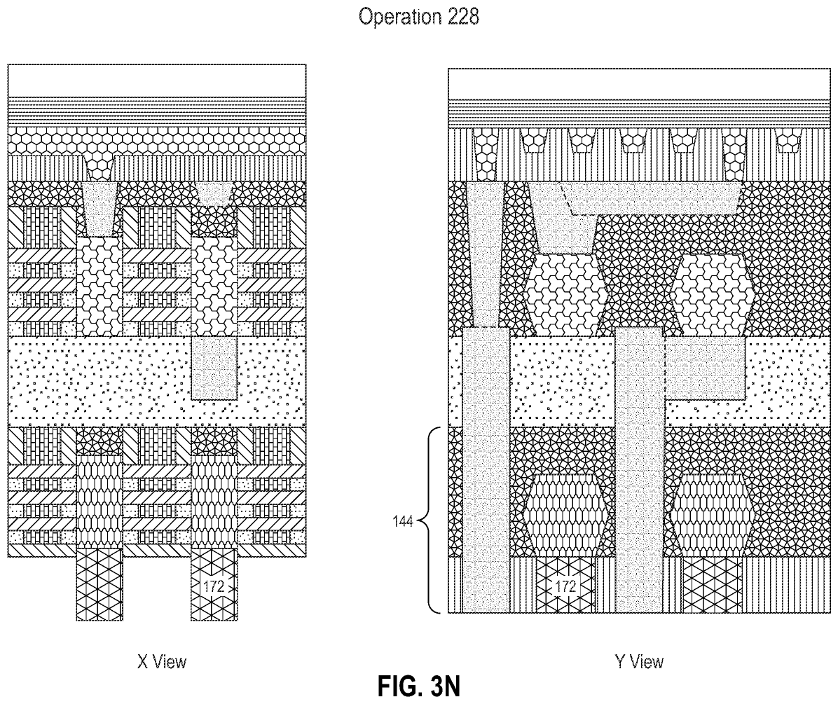

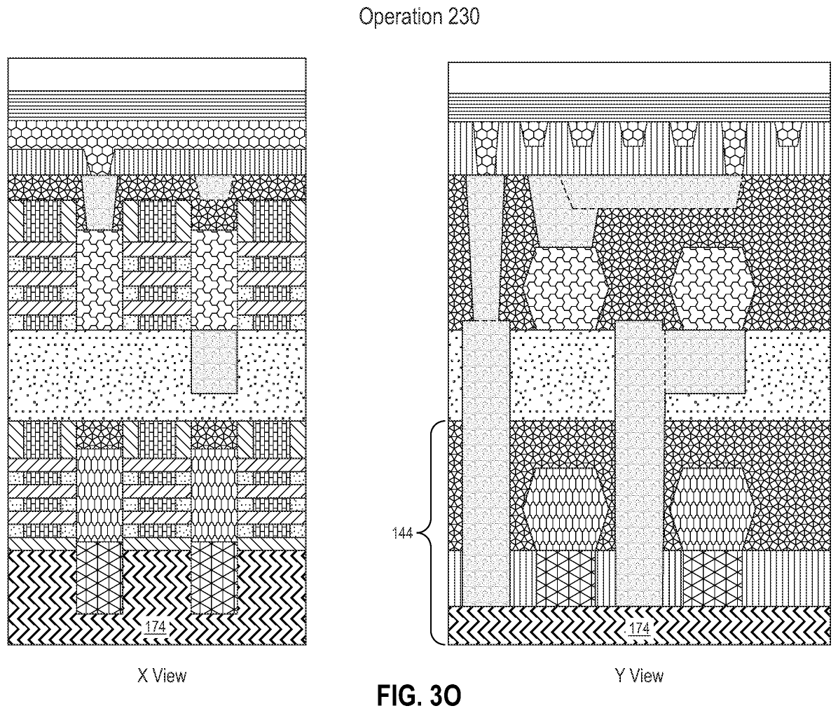

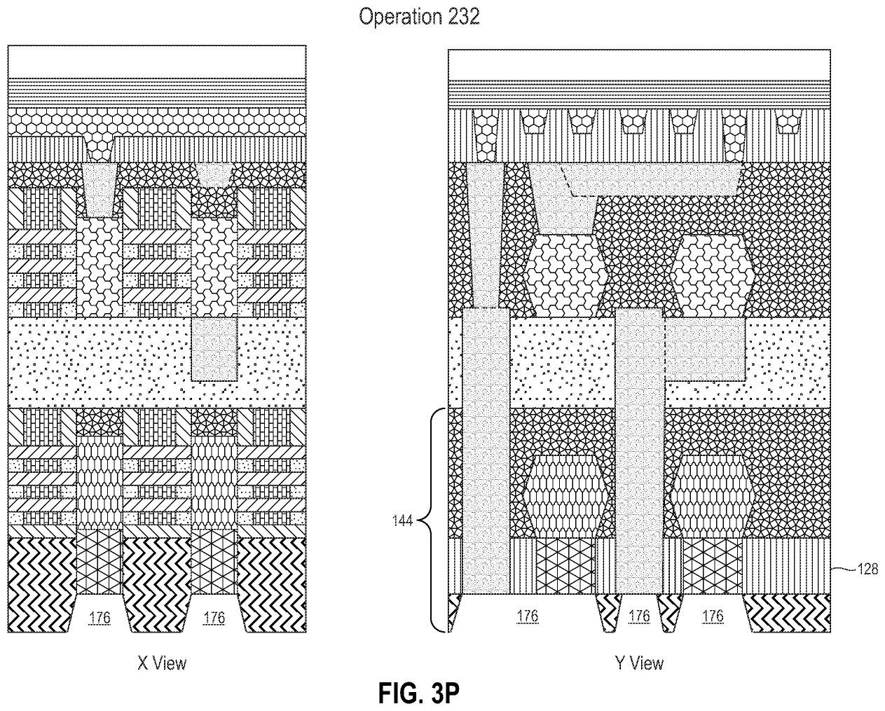

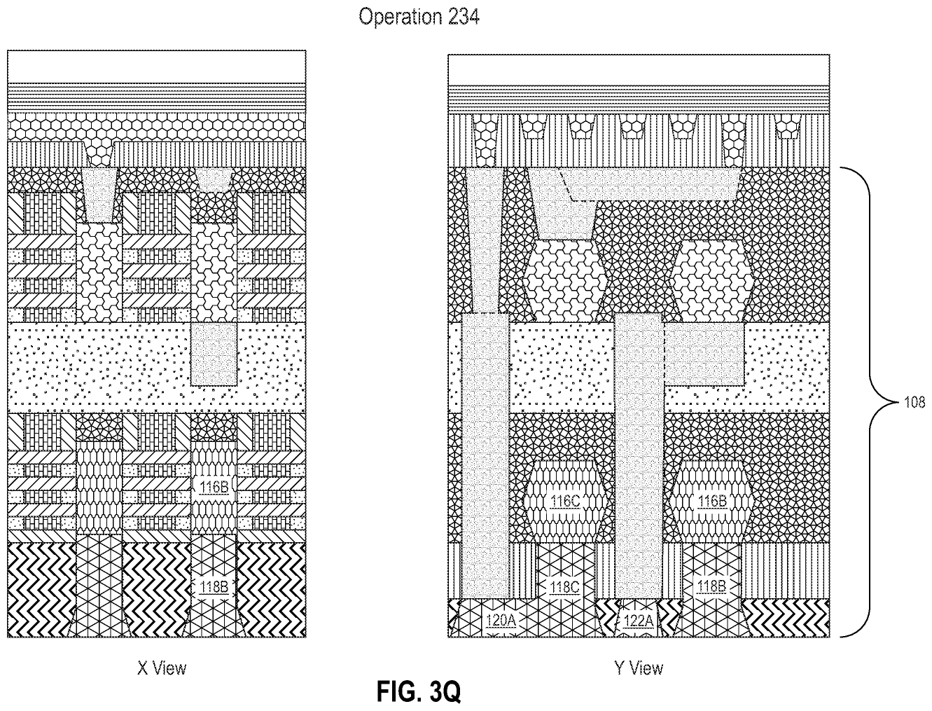

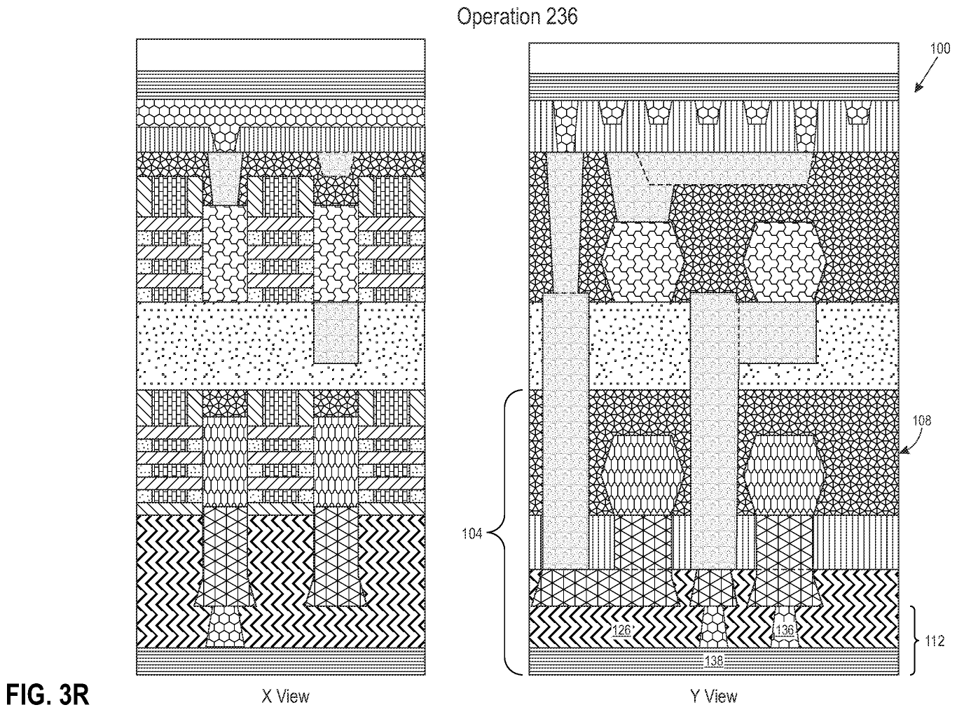

Another way of describing semiconductor structure 100 is that semiconductor structure 100 is comprised of device region 108 with a top interconnect 110 connected to the top of device region 108 and bottom interconnect 112 connected to the top of device region 108. In the illustrated embodiment, device region 108 comprises gates 114, source/drain epitaxials (“S/Ds”) 116A-116D (collectively “S/Ds 116”), contacts 118A-118D (collectively “contacts 118”), local interconnects (“LIs”) 120A-120B (collectively, “LIs 120”), vias 122A-122B (collectively, “vias 122”), and insulating member 124. Insulating member 124 electrically insulates some of gates 114, S/Ds 116, contacts 118, LIs 120, and vias 122 from each other, and insulating member 124 comprises bonding layer 106, bottom interlayer dielectric (BILD) 126, shallow trench isolation (STI) 128, interlayer dielectric (ILD) 130, and ILD 132. Each of the layers of insulating member 124 (i.e., 106/126/128/130/132) can be comprised of a medium dielectric constant material (a.k.a. mid-κ), such as, for example, silicon nitride (SiN), silicon dioxide (SiO₂), silicon nitride carbide (SiNC), tetraethyl orthosilicate (TEOS), silicon oxycarbide (SiCOx), silicon oxycarbonitride (SiCNO), or siliconboron carbonitride (SiBCN), or a mixture of one or more of the aforementioned materials. The layers of insulating member 124 can be comprised of the same material or different materials, and a material can appear in multiple layers. While one embodiment of insulating member 124 is shown in FIG. 1A, other configurations and combinations of layers (e.g., STI, ILD, etc.) are possible. In addition, due to BILD 126 being extended in the method of manufacture of semiconductor structure 100 (see FIG. 3R), a portion of BILD 126 is part of insulating member 124 and the other portion is part of bottom interconnect 112.

In the illustrated embodiment, gates 114 and S/Ds 116 are selectively electrically connected to form FETs 134. In order for semiconductor structure 100 to function as intended, connections are made within device region 108. These connections can be further connected to top interconnect 110 and/or bottom interconnect 112. For example, S/D 116A is positioned wholly in ILD 132, and the bottom side of S/D 116A (i.e., the side nearest to S/D 116B) is in contact with and electrically connected to contact 118A. Contact 118A is positioned wholly in bonding layer 106, and the lateral side of contact 118A is in contact with and electrically connected to via 122A on the end nearest to S/D 116D. Via 122A extends through isolating member 124 (i.e., the bottom side of via 122A is not covered by isolating member 124) and is in contact with and electrically connected to bottom interconnect 112. Via 122A extends past S/Ds 116B and 116C but is electrically insulated therefrom by isolating member 124. For another example, S/D 116B is positioned wholly in ILD 130, and the bottom side of S/D 116B (i.e., the side nearest to bottom interconnect 112) is in contact with and electrically connected to contact 118B. Contact 118B is positioned within both BILD 126 and STI 128 and is in contact with and electrically connected to bottom interconnect 112. For another example, S/D 116C is positioned wholly in ILD 130, and the bottom side of S/D 116C (i.e., the side arranged nearest to bottom interconnect 112) is in contact with and electrically connected to contact 118C. Contact 118C is positioned wholly in STI 128 and is in contact with and electrically connected to LI 120A on the bottom side of contact 118C. LI 120A is positioned wholly in BILD 126 and extends laterally. The top of LI 120A is in contact with and electrically connected to via 122B. Accordingly, LI 120A can also be referred to as an extended backside contact. Via 122B extends through isolating member 124 (i.e., the top side of via 122A is not covered by isolating member 124) and is in contact with and electrically connected to top interconnect 110. For another example, S/D 116D is positioned wholly in ILD 132, and the top side of S/D 116D (i.e., the side nearest to top interconnect 110) is in contact with and electrically connected to contact 118D. Contact 118D is positioned wholly in ILD 132, and the top and lateral sides of contact 118D are in contact with and electrically connected to LI 120B. LI 120B is positioned wholly in ILD 132 and extends laterally in the vertical space between top interconnect 110 and S/D 116A. LI 120B is in contact with and electrically connected to top interconnect 110 but is electrically insulated from S/D 116A by ILD 132 of isolating member 124. Thus, the components and configuration of device region 108 allow for S/Ds 116A and 116D to be positioned in top channel 102 and be connected to top interconnect 110 and/or bottom interconnect 112, respectively. Similarly, S/Ds 116B and 116C can be positioned in bottom channel 104 and be connected to top interconnect 110 and/or bottom interconnect 112, respectively.

What is shown in FIG. 1A is merely a portion of a larger integrated circuit. In general, top interconnect 110 and bottom interconnect 112 extend laterally, and top interconnect 110 and bottom interconnect 112 are on opposing sides of and separated by the longitudinal thickness of device region 108. Device region 108 also extends laterally with top interconnect 110 and bottom interconnect 112. For clarity, lateral axes 140A and 140B (collectively “lateral axes 140”) and longitudinal axes 142A-142C (collectively “longitudinal axes 142”) have been added to FIG. 1A. Lateral axes 140 extend in a lateral direction (i.e., left-and-right, as shown in the Y View of FIG. 1A), and longitudinal axes 142 extend in a longitudinal direction (i.e., up-and-down, as shown in the Y View of FIG. 1A).

Furthermore, lateral axes 140 and longitudinal axes 142 intersect with certain features of semiconductor structure 100 (e.g., S/Ds 116) to show spacial relationships therebetween. For example, in the illustrated embodiment, S/D 116B is longitudinally offset from S/D 116A (as indicated by lateral axes 140A and 140B being spaced apart), but S/D 116B is laterally aligned with S/D 116A (as indicated by the centers of both being located on longitudinal axis 142A). However, in some embodiments, S/D 116B merely laps (e.g., overlaps in part) S/D 116A laterally. Lapping in this context can mean that a longitudinal axis (e.g., longitudinal axis 142A passes through any portion of each of the pair of S/Ds (e.g., S/D 116A and 116B), regardless if the portions are the same (e.g., through the centers of both) or different (e.g., the right of one and the left side of the other). S/D 116D is longitudinally offset from S/D 116C (as indicated by lateral axes 140A and 140B being spaced apart), but S/D 116D is laterally aligned with S/D 116C (as indicated by the centers of both being located on longitudinal axis 142B). However, in some embodiments, S/D 116D merely laps (e.g., overlaps in part) S/D 116C laterally. Furthermore, S/D 116D is laterally offset from S/D 116A (as indicated by longitudinal axes 142A and 142B being spaced apart), but S/D 116D is longitudinally aligned with S/D 116A (as indicated by the centers of both being located on lateral axis 140A). However, in some embodiments, S/D 116D merely laps (e.g., overlaps in part) S/D 116A longitudinally. S/D 116C is laterally offset from S/D 116B (as indicated by longitudinal axes 142A and 142B being spaced apart), but S/D 116C is longitudinally aligned with S/D 116B (as indicated by the centers of both being located on lateral axis 140B). However, in some embodiments, S/D 116C merely laps (e.g., overlaps in part) S/D 116B longitudinally. In addition, LI 120B laterally laps S/D 116A and S/D 116B (as indicated by longitudinal axis 142A intersecting LI 120B), and LI 120B laterally laps via 122A (as indicated by longitudinal axis 142C, along which via 122A extends, intersecting LI 120B). Thus, FETs 134 are longitudinally offset from each other, but FETs 134 are laterally aligned with each other. However, in some embodiments, FETs 134 merely lap (e.g., overlap in part) each other laterally.

In the illustrated embodiment, top interconnect 110 and bottom interconnect 112 include vias 136 and interconnection layers 138 that are selectively connected to vias 136 to route signals to and/or from device region 108. Top interconnect 110 also includes carrier wafer 139. The signal transmission components (i.e., 118/120/122/136/138) are comprised of an electrically conductive material, such as metal (e.g., titanium nitride (TiN), cobalt (Co), ruthenium (Ru), molybdenum (Mo), or tungsten (W)). The signal transmission components can be comprised of the same material or different materials, and a material can appear in multiple components. Thereby, semiconductor structure 100 can function as designed and intended.

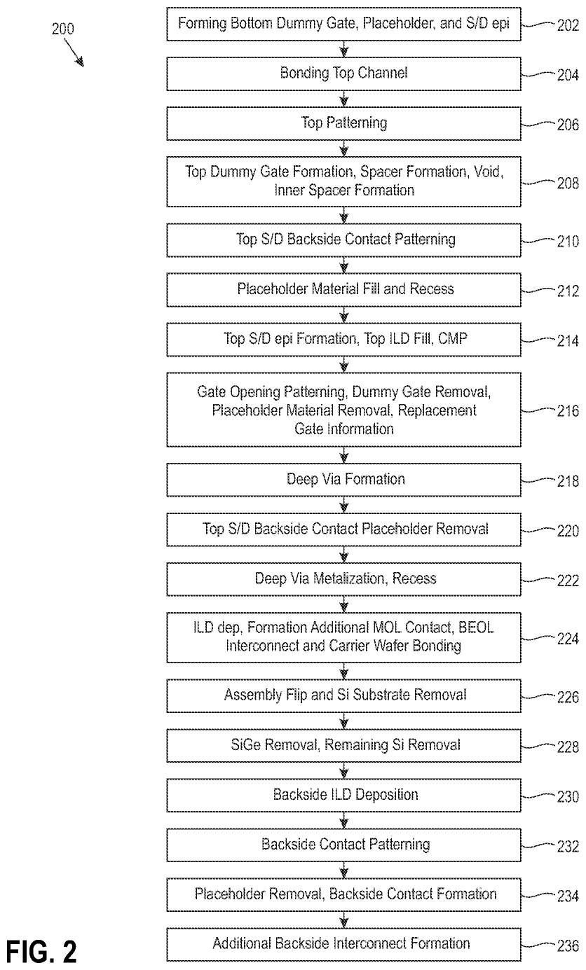

FIG. 2 is a flowchart of method 200 of manufacturing semiconductor structure 100. FIGS. 3A-3R are a series of cross-section views of stages in a manufacture of semiconductor structure 100 according to method 200. The results of each operation in method 200 is illustrated in one of FIGS. 3A-3R, so FIGS. 2 and 3A-3R will be discussed in conjunction with one another. In addition, during this discussion, references may be made to features of semiconductor structure 100 (shown in FIG. 1A), however, some features may be omitted for the sake of simplicity.

In the illustrated embodiment, method 200 begins having been provided bottom device materials 144 (shown in FIG. 3A), some of which can become part of bottom channel 104 (shown in FIG. 1A). At operation 202 (shown in FIG. 3A), S/Ds 116B and 116C, placeholder material 146 (e.g., a sacrificial silicon germanium sheet), and dummy gates 148 are formed in bottom device materials 144. At operation 204 (shown in FIG. 3B), top device materials 150, some of which can become part of top channel 102 (shown in FIG. 1A), is bonded to bottom device materials 144 with bonding material 152. At operation 206 (shown in FIG. 3C), top device materials 150 is patterned and material is removed therefrom. At operation 208 (shown in FIG. 3D), dummy gates 154, spacers 156, void 158 (voids are also known as cavities), and inner spacers 160 are formed. At operation 210 (shown in FIG. 3E), mask 162 is formed and material is removed from top device materials 150 and bonding material 152 to form void 164. Void 164 is bounded by bonding material 152 and the same portion of top device materials 150 that bordered former void 158 (shown in FIG. 3D). Void 164 will eventually be filled, in part, by S/D 116A and contact 118A (both shown in phantom in FIG. 3E). While contact 118A has a different, wider width than S/D 116A in the lateral y-direction (as shown in the Y View), S/D 116A and contact 118A have the same width in the lateral x-direction (as shown in the X View). This is because void 164 is finalized in a single step, ensuring self-alignment of S/D 116A and contact 118A, at least in the lateral x-direction, ensuring an electrical connection between S/D 116A and contact 118A.

In the illustrated embodiment, at operation 212 (shown in FIG. 3F), placeholder material 166 is formed in void 164 (shown in FIG. 3E), and mask 162 (shown in FIG. 3E) is removed and placeholder material 166 is recessed flush with the top of bonding material 152. At operation 214 (shown in FIG. 3G), S/Ds 116A and 116D are formed on bonding material 152 and placeholder material 166, respectively. Also, ILD layer 167 is formed and planarized to be flush with the tops of dummy gates 154 and spacers 156. At operation 216 (shown in FIG. 3H), gate patterning is performed, and placeholder material 146 and dummy gates 148 and 154 (shown in FIGS. 3A and 3D, respectively) are removed. In their places, gates 114 are formed. At operation 218 (shown in FIG. 3I), mask 168 is formed on top device materials 150, and deep voids 170A and 170B are formed through top device materials 150 (including some of placeholder material 166 but not through any of S/D 116A) and through some of bottom device materials 144. Thereby, operation 218 completes bonding layer 106 and ILD 130. At operation 220 (shown in FIG. 3J), the remaining portion of placeholder material 166 and mask 168 (both shown in FIG. 3I) are removed, which exposes the bottom side of S/D 116A. At operation 222 (shown in FIG. 3K), deep voids 170A and 170B are metalized and then recessed to form contact 118A, a portion of via 122A (labeled 122A′), and a portion of via 122B (labeled 122B′). At operation 224 (shown in FIG. 3L), additional ILD material is deposited into deep void 170A (shown in FIG. 3K) to electrically insulate the upper end of via 122A, and the remainder of deep void 170B is metalized to form via 122B. Also at operation 224, contact 118D is formed on the top side of S/D 116D, and LI 120B is formed on contact 118D. Thus, ILD 132 is completed. Top interconnect 110 is also formed on the top of the existing device region 108 (labeled 108′), so top channel 102 is completed.

In the illustrated embodiment, at operation 226 (shown in FIG. 3M), the partially-formed assembly that has been made so far is flipped to provide access to its bottom side. (However, the orientation has not changed from FIG. 3L to FIG. 3M for visual continuity.) Subsequently, but also at operation 226, some of bottom device materials 144 (e.g., a silicon substrate) is removed. At operation 228 (shown in FIG. 3N), some more of bottom device materials 144 (e.g., a silicon germanium layer and/or a silicon substrate) is removed to expose placeholder material 172. At operation 230 (shown in FIG. 3O), BILD material 174 is added to bottom device materials 144. At operation 232 (shown in FIG. 3P), bottom device materials 144 is patterned and material is selectively removed from bottom device materials 144 to form voids 176 and complete STI 128. At operation 234 (shown in FIG. 3Q), placeholder material 172 (shown in FIG. 3N) is removed to expose the bottom sides of S/Ds 116B and 116C. Also at operation 234, voids 176 (shown in FIG. 3O) are metalized to form contacts 118B and 118C, LI 120A, and via 122A to complete device region 108. At operation 236 (shown in FIG. 3R), bottom interconnect 112 (including vias 136 and interconnection layers 138) is formed on the bottom of device region 108 to complete BILD 126, bottom channel 104, and semiconductor structure 100.

The result of method 200 is a semiconductor structure with a front side FET with a self-aligned S/D and contact that is communicatively connected to the bottom interconnect. In addition, space is freed up above the front side FET that can be used by interconnects for other FETs. Overall, the features of the present disclosure enable more freedom in the design of the semiconductor structure because there is more flexibility in the positioning of the FETs and the routes of the interconnects.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure that extends laterally with a first interconnect on one side and a second interconnect on an opposing side separated from the first interconnect by a thickness of the semiconductor structure that extends longitudinally, the semiconductor structure comprising:
an insulating member extending laterally;
a first source/drain (S/D) positioned in the insulating member between the first interconnect and the second interconnect;
a second S/D positioned in the insulating member between the first S/D and the second interconnect, wherein the second S/D laps the first S/D laterally and is offset from the first S/D longitudinally; and
a first via electrically connected to the first S/D and to the second interconnect.

2. The semiconductor structure of claim 1, further comprising:
a third S/D positioned in the insulating member between the first interconnect and the second interconnect, wherein the third S/D laps the first S/D longitudinally and is offset from the first S/D laterally; and
a local interconnect that is electrically connected to the third S/D and to the first interconnect and is electrically insulated from the first S/D;
wherein the local interconnect laps the first S/D laterally and is offset from the first S/D longitudinally.

3. The semiconductor structure of claim 1, further comprising a second via electrically connected to the second S/D and to the second interconnect.

4. The semiconductor structure of claim 1, further comprising a contact connected to the first S/D on a side nearest to the second S/D.

5. The semiconductor structure of claim 4, wherein the insulating member comprises a bonding dielectric layer longitudinally positioned between the first S/D and the second S/D.

6. The semiconductor structure of claim 5, wherein the contact is positioned in the bonding layer.

7. The semiconductor structure of claim 4, wherein the first via is electrically connected to the first S/D through the contact.

8. The semiconductor structure of claim 4, wherein:
the contact is a same width as the first S/D in a first lateral direction; and
the contact is a larger width than the first S/D in a second, different lateral direction.

9. The semiconductor structure of claim 1, further comprising a second via electrically connected to the second S/D and to the second interconnect.

10. The semiconductor structure of claim 9, further comprising a third S/D positioned in the insulating member between the first interconnect and the second interconnect, wherein the third S/D laps the second S/D longitudinally and is offset from the second S/D laterally, wherein the third S/D is electrically connected to the first interconnect.

11. A method of forming a semiconductor structure, the method comprising:
forming a first source/drain (S/D) in a first device materials;
bonding a second device materials to the first device materials using a bonding dielectric;
forming a dummy gate and a spacer in the second device materials;
forming a second S/D contact placeholder in the bonding dielectric;
forming a second S/D in the second device materials;
forming a deep via trench in the first device materials, in the second device materials, and in the contact placeholder;
forming a via in the deep via trench that is electrically connected to the second S/D;
forming a second-side interconnect on the second device materials;
forming a local interconnect in the second device materials that intersects an axis of the via but is electrically insulated from the via; and
forming a first-side interconnect on the first device materials.

12. The method of claim 11, wherein:
the method further comprises removing a remaining portion of the contact placeholder; and
the forming the local interconnect is performed such that the local interconnect intersects an axis extending between the first S/D and the second S/D.

13. The method of claim 11, wherein forming the second-side interconnect comprises:
removing a portion of the second device materials; and
forming the second-side interconnect on a remaining second device materials.

14. The method of claim 13, further comprising forming a void in the second device materials prior to forming the second S/D contact placeholder such that the second S/D is self-aligned with the second S/D contact.

15. The method of claim 11, wherein forming the via comprises forming a contact in a void left by the removal of the remaining portion of the contact placeholder, wherein the contact is electrically connected to the deep via trench and to the second S/D.

16. The method of claim 11, wherein the forming the local interconnect comprises electrically connecting the local interconnect to a third S/D and to the second-side interconnect but not to the second S/D.

17. The method of claim 11, wherein forming the first-side interconnect comprises:
removing a portion of the first device materials; and
forming the first-side interconnect on a remaining first device materials.

18. A semiconductor structure that extends laterally with a first interconnect on one side and a second interconnect on an opposing side separated from the first interconnect by a thickness of the semiconductor structure that extends longitudinally, the semiconductor structure comprising:
an insulating member extending laterally;
a first source/drain (S/D) positioned in the insulating member between the first interconnect and the second interconnect;
a second S/D positioned in the insulating member between the first interconnect and the second interconnect, wherein the second S/D laps the first S/D longitudinally and is offset from the first S/D laterally; and
a local interconnect that is electrically connected to the second S/D and to the first interconnect and is electrically insulated from the first S/D;
wherein the local interconnect laps the first S/D laterally and is offset from the first S/D longitudinally.

19. The semiconductor structure of claim 18, further comprising a first via electrically connected to the first S/D and to the second interconnect.

20. The semiconductor structure of claim 18, further comprising a third S/D positioned in the insulating member between the first S/D and the second interconnect, wherein the third S/D laps the first S/D laterally and is offset from the first S/D longitudinally.
